(19) United States
(12) Patent Application Publication
(10) Pub. No.: US 2010/0240154 A1
(43) Pub. Date: Sep. 23, 2010

(54) TEMPERATURE CONTROL DEVICE, TEMPERATURE CONTROL METHOD, AND SUBSTRATE PROCESSING APPARATUS

(75) Inventor: Toshifumi Ishida, Nirasaki (JP)

Correspondence Address: PEARNE & GORDON LLP, 1801 EAST 9TH STREET, SUITE 1200, CLEVELAND, OH, 44114-3108, US

(73) Assignee: TOKYO ELECTRON LIMITED, Tokyo (JP)

(21) Appl. No.: 12/726,602

(22) Filed: Mar. 18, 2010

Related U.S. Application Data
(60) Provisional application No. 61/224,174, filed on Jul. 9, 2009.

(30) Foreign Application Priority Data
Mar. 19, 2009 (JP) 2009-068287

(51) Int. Cl. H01L 21/465

(52) U.S. Cl. 438/5; 156/345.27; 257/E21.485

(57) ABSTRACT

Provided is a temperature control device for controlling a temperature of a member to be exposed to plasma in a substrate processing apparatus. The substrate processing apparatus includes a mounting electrode for mounting a target substrate and a facing electrode positioned to face the mounting electrode, excites a processing gas supplied between the mounting electrode and the facing electrode into plasma, and performs a plasma process on the target substrate with the plasma. The temperature control device includes a heating layer configured to heat a heating target member, a heat insulating layer positioned in contact with an opposite surface to a heating layer's surface facing the heating target member, and a cooling layer positioned in contact with an opposite surface to a heat insulating layer's surface facing the heating layer.

### CROSS-REFERENCE TO RELATED APPLICATION

This application claims the benefit of Japanese Patent Application No. 2009-068287 filed on Mar. 19, 2009, and U.S. Provisional Application Ser. No. 61/224,174 filed on Jul. 9, 2009, the entire disclosures of which are incorporated herein by reference.

### FIELD OF THE INVENTION

The present disclosure relates to a temperature control device, a temperature control method, and a substrate processing apparatus. In particular, the present disclosure relates to a temperature control device, a temperature control method, and a substrate processing apparatus for controlling a temperature of an internal member of a substrate processing apparatus to be exposed to plasma.

### BACKGROUND OF THE INVENTION

A substrate processing apparatus, which performs a plasma process on a semiconductor wafer (hereinafter, simply referred to as “wafer”) serving as a substrate, includes a chamber (processing chamber) that accommodates a wafer and can be depressurized; a susceptor (mounting table) positioned on the lower part within the chamber; and a shower head (upper electrode) positioned within the chamber to face the susceptor. The susceptor is configured to mount thereon the wafer and serves as a mounting electrode applying a high frequency power from a connected high frequency power supply into the chamber. The shower head introduces a processing gas into the chamber and is grounded to serve as a facing electrode. In this substrate processing apparatus, the processing gas supplied into the chamber is excited into plasma by the high frequency power and the wafer is plasma-processed by the plasma.

In this case, at the time of starting the process on the wafer, it is required to heat an internal member of the substrate processing apparatus to a predetermined temperature. Therefore, various kinds of temperature controlling technologies have been developed.

FIG. 5 is a schematic cross-sectional view of a configuration of a conventional substrate processing apparatus including a temperature control device for its internal member.

A substrate processing apparatus 100 illustrated in FIG. 5 includes a cylindrical chamber 101 in which an upper electrode 103 positioned to face a susceptor 102 is formed into a substantially circular plate shape having an outer diameter substantially the same as an inner diameter of the chamber 101. The upper electrode 103 is configured to vertically move like a piston in the chamber 101 by a non-illustrated lift mechanism.

The upper electrode 103 includes a facing electrode plate (upper electrode member) 104, a buffer room 105, and gas holes 106. The buffer room 105 and an inner space of the chamber 101 are communicated by the gas holes 106. Installed on the upper electrode member 104 serving as a heating target member to be heated by the plasma is a temperature control device 113 including a cooling layer 111 and a heating layer 112 positioned on the cooling layer 111. As a coolant for the cooling layer 111, there has been used a fluorine-based nonreactive liquid such as Fluorinert (registered trademark of 3M Corp.).

In the substrate processing apparatus 100 configured as stated above, the temperature of the upper electrode member 104 is increased by a heater as the heating layer 112 of the temperature control device 113. Further, the cooling layer 111 is configured to cool the upper electrode member 104 to decrease the temperature thereof.

Such a temperature control device for controlling a temperature of a member within a substrate processing apparatus is disclosed in, for example, Patent Document 1.

Patent Document 1: Japanese Patent Laid-open Publication No. 2004-342704

### BRIEF SUMMARY OF THE INVENTION

However, the conventional technology has a problem of a poor responsiveness to temperature increase since the heating layer 112 is in indirect contact with the upper electrode member 104 serving as the heating target member with the cooling layer 111 interlayered therebetween. Further, although the fluorine-based nonreactive liquid, which has high temperature durability, has been used as a coolant, another heat exchanger is needed to maintain the temperature of the coolant. Accordingly, a configuration of the apparatus becomes complicated, resulting in problems such as high manufacturing cost.

In a recent substrate processing apparatus, at the time of lot start, the inside of the chamber needs to have the temperature of, e.g., about 220° C. higher than a temperature conventionally needed. Therefore, there is a problem in that Fluorinert (registered trademark of 3M Corp.) having an upper temperature limit of about 150° C. cannot be used as a coolant. Further, it is necessary to arrange the cooling layer and the heater apart from each other to prevent the coolant from being overheated or boiled, resulting in problems such as low responsiveness to temperature decrease. Furthermore, no fluid coolant having durability to high temperature of about 220° C. has been found, and, thus, the cooling layer and the heating layer should be used together. Accordingly, a configuration of the apparatus becomes complicated, resulting in problems such as high manufacturing cost.

In view of the foregoing, the present disclosure provides a temperature control device, a temperature control method, and a substrate processing apparatus having a non-complicated configuration even if the cooling layer and the heating layer are used together, and, further, having excellent responsiveness to heating and cooling.

In order to solve the above-mentioned problem, in accordance with one aspect of the present disclosure, there is provided a temperature control device for controlling a temperature of a member to be exposed to plasma in a substrate processing apparatus. The substrate processing apparatus includes a mounting electrode for mounting a target substrate and a facing electrode positioned to face the mounting electrode, excites a processing gas supplied between the mounting electrode and the facing electrode into plasma, and performs a plasma process on the target substrate with the plasma. The temperature control device includes: a heating layer configured to heat a heating target member; a heat insulating layer positioned in contact with an opposite surface to a heating layer's surface facing the heating target member; and a cooling layer positioned in contact with an opposite surface to a heat insulating layer's surface facing the heating layer.

In the temperature control device, a coolant for the cooling layer is running water and a temperature of water discharged from the cooling layer does not exceed a boiling point of water.

In the temperature control device, if a thermal conductivity of the heat insulating layer is denoted by λ(W/m·K) and its thickness is denoted by d(m), λ/d satisfies an inequality (1).

44<λ/d<220 (1)

In the temperature control device, if a temperature of the heating layer's surface facing the heat insulating layer is denoted by t1° C. and a temperature of the heating layer's surface facing the heating target member is denoted by t2° C., λ/d satisfies an equality (2).

λ/d=(−26721·t2+15269·t1+2109195)/(t1−128.7) (2)

In the temperature control device, if a temperature of the heating layer's surface facing the heat insulating layer is denoted by t1° C. and a temperature of the heating layer's surface facing the heating target member is denoted by t2° C., t2 satisfies an inequality (3).

0.56·t1+77≦t2≦0.57·t1+82 (3)

In the temperature control device, the heating target member is an electrode plate of the facing electrode and is installed above the mounting electrode to face the mounting electrode.

Further, in accordance with another aspect of the present invention, there is provided a temperature control method for controlling a temperature of a member to be exposed to plasma in a substrate processing apparatus. The substrate processing apparatus includes a mounting electrode for mounting a target substrate and a facing electrode positioned to face the mounting electrode, excites a processing gas supplied between the mounting electrode and the facing electrode into plasma, and performs a plasma process on the target substrate with the plasma. The temperature control method includes: using a temperature control device which includes a heating layer configured to heat a heating target member, a heat insulating layer positioned in contact with an opposite surface to a heating layer's surface facing the heating target member, and a cooling layer positioned in contact with an opposite surface to a heat insulating layer's surface facing the heating layer; and adjusting a temperature of the heating target member to a predetermined temperature by maintaining a balance between heating and cooling by increasing or decreasing a heating temperature of the heating layer while cooling the heating target member with running water serving as a coolant for the cooling layer.

In the temperature control method, the predetermined temperature is in a range from about 60° C. to about 220° C.

Furthermore, in accordance with still another aspect of the present invention, there is provided a substrate processing apparatus including a mounting electrode for mounting a target substrate and a facing electrode positioned to face the mounting electrode. The substrate processing apparatus excites a processing gas supplied between the mounting electrode and the facing electrode into plasma, and performs a plasma process on the target substrate with the plasma. Further, the substrate processing apparatus includes: a temperature control device for controlling a temperature of a member to be exposed to the plasma.

The above-mentioned temperature control device and the above-mentioned substrate processing apparatus include the heating layer for heating the heating target member, the heat insulating layer positioned in contact with the opposite surface to the heating layer's surface facing the heating target member, and the cooling layer positioned in contact with the opposite surface to the heat insulating layer's surface facing the heating layer. Therefore, in spite of use of the cooling layer with the heating layer, a configuration of the apparatus does not become complicated. Further, when the temperature of the heating target member is adjusted to a predetermined temperature by an interaction between direct heating by the heating layer and indirect cooling by the cooling layer, favorable responsiveness to heating and cooling can be achieved.

In the temperature control device, running water is used as a coolant for the cooling water and the temperature of water discharged from the cooling layer does not exceed the boiling point of water, and, thus, it is not necessary to install any additional device such as a valve for controlling a start and a stop of the supply of the running water, and controllability can be improved while ensuring safety.

In the temperature control device, if a thermal conductivity of the heat insulating layer is denoted by λ(W/m·K) and its thickness is denoted by d(m), λ/d satisfies the following inequality (1), and, thus, selectivity of the heat insulating material can be enhanced.

44<λ/d<220 (1)

In the temperature control device, if a temperature of the heating layer's surface facing the heat insulating layer is denoted by t1° C. and a temperature of the heating layer's surface facing the heating target member is denoted by t2° C., λ/d satisfies the following equality (2). Therefore, the temperature of the heating target member can be adjusted with more accuracy by the heat insulating layer having an optimum thickness and an optimum thermal conductivity.

λ/d=(−26721·t2+15269·t1+2109195)/(t1−128.7) (2)

In the temperature control device, if a temperature of the heating layer's surface facing the heat insulating layer is denoted by t1° C. and a temperature of the heating layer facing the heating target member is denoted by t2° C., t2 satisfies the following inequality (3). Therefore, it is possible to easily control a heating temperature.

0.56·t1+77≦t2≦0.57·t1+82 (3)

In the temperature control device, the heating target member is an electrode plate of the facing electrode and is installed above the mounting electrode so as to face the mounting electrode. Thus, the temperature of the upper electrode member can be adjusted to a predetermined temperature with favorable responsiveness to heating and cooling.

The temperature control method uses the temperature control apparatus including the heating layer for heating the heating target member, the heat insulating layer positioned in contact with the opposite surface to the heating layer's surface facing the heating target member, and the cooling layer positioned in contact with the opposite surface to the heat insulating layer's surface facing the heating layer. The temperature of the heating target member is adjusted to a predetermined temperature by maintaining a balance between heating and cooling by increasing or decreasing a heating temperature of the heating layer while cooling the heating target member with running water serving as a coolant for the cooling layer. Therefore, the temperature of the heating target member can be adjusted to a predetermined temperature with favorable responsiveness to heating and cooling.

In the temperature control method, the predetermined temperature is in a range from about 60° C. to about 220° C. Therefore, it is possible to meet a temperature condition of the member in the substrate processing apparatus at the time of lot start, which is recently demanded.

### BRIEF DESCRIPTION OF THE DRAWINGS

The disclosure may best be understood by reference to the following description taken in conjunction with the following figures:

FIG. 1 is a schematic cross-sectional view of a configuration of a substrate processing apparatus including a temperature control device in accordance with an embodiment of the present invention;

FIG. 2 is a graph showing a relationship between a temperature of a heating layer's surface facing a heat insulting layer and a temperature of a heating layer's surface facing an upper electrode layer;

FIG. 3 is a graph showing changes in a temperature of an upper electrode layer in accordance with an experimental example;

FIG. 4 is an enlarged view of a part of FIG. 3; and

FIG. 5 is a schematic cross-sectional view of a configuration of a conventional substrate processing apparatus including a temperature control device for its internal member.

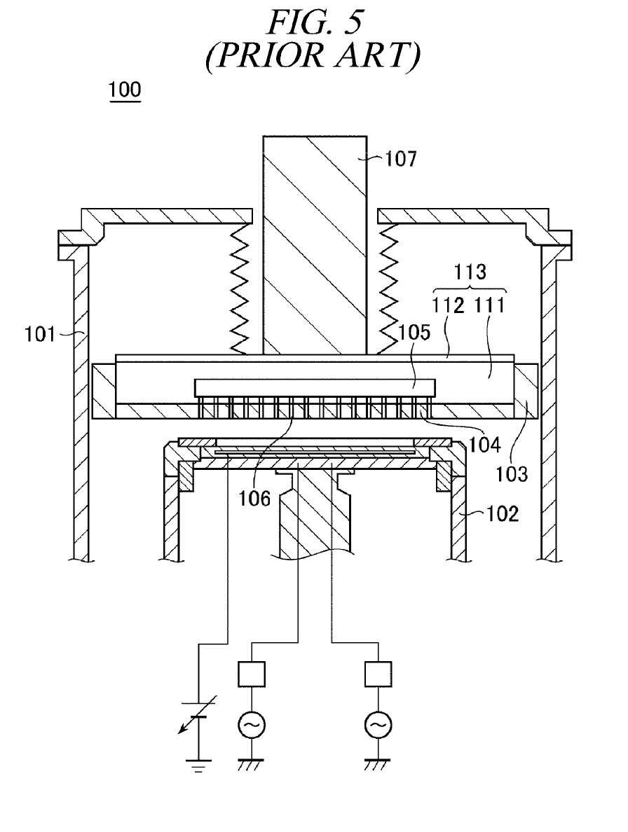

### DETAILED DESCRIPTION OF THE INVENTION

Hereinafter, embodiments of the present invention will be described in detail with reference to the accompanying drawings.

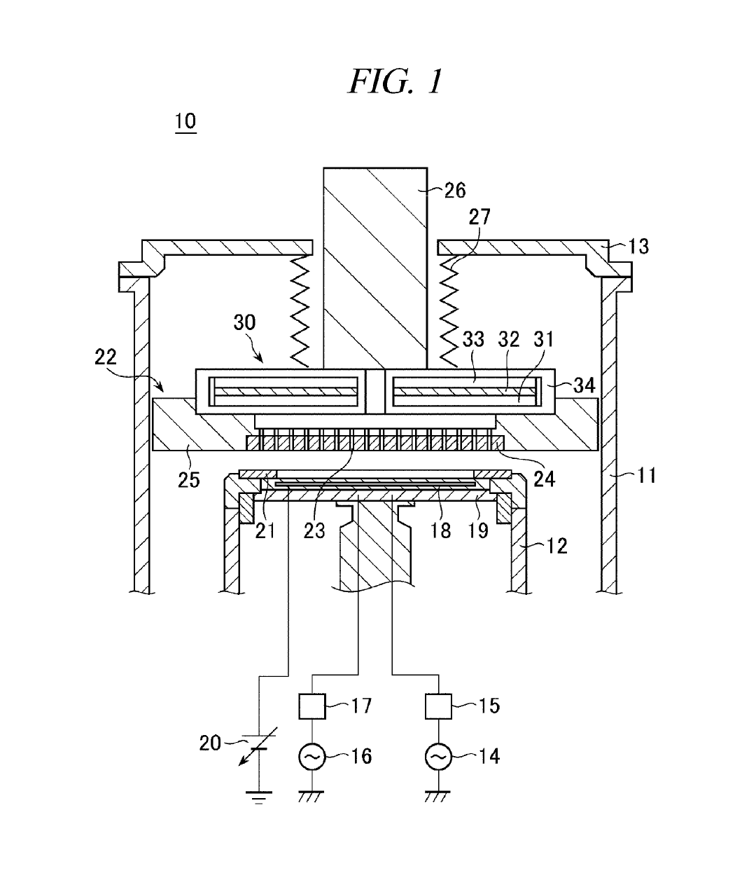

FIG. 1 is a schematic cross-sectional view of a configuration of a substrate processing apparatus including a temperature control device in accordance with an embodiment of the present invention. The temperature control device of the substrate processing apparatus is configured to control a temperature of an upper electrode member within a processing chamber.

As illustrated in FIG. 1, a substrate processing apparatus 10 includes a cylindrical chamber (processing chamber) 11 accommodating a wafer W of, e.g., about 300 mm in diameter. Further, a cylindrical susceptor (mounting electrode) 12 mounting thereon the wafer W for a semiconductor device is installed at the lower part of the chamber 11 and an openable/closable cover 13 having a circular plate shape covers the upper part of the chamber 11.

The inside of the chamber 11 is depressurized by a TMP (Turbo Molecular Pump) and a DP (Dry Pump) (both not illustrated), and an internal pressure of the chamber 11 is controlled by an APC valve (not illustrated). Further, although even nano-sized particles is adhered to the semiconductor device, they can be a cause of defects of the semiconductor device, and, thus, particles inside the chamber 11 are removed by a cleaning process prior to a dry etching process.

The susceptor 12 is connected with a first high frequency power supply 14 via a first matching unit 15 and with a second high frequency power supply 16 via a second matching unit 17. The first high frequency power supply 14 is configured to apply a high frequency bias power having a relatively low frequency of, e.g., about 3.2 MHz to the susceptor 12, whereas the second high frequency power supply 16 is configured to apply a plasma-generating high frequency power having a relatively high frequency of, e.g., about 100 MHz to the susceptor 12. The susceptor 12 applies the plasma-generating power to the inside of the chamber 11.

Installed at the upper part of the susceptor 12 is an electrostatic chuck 19 including therein an electrostatic electrode plate 18. The electrostatic chuck 19 is made of a ceramic member having a circular plate shape, and the electrostatic electrode plate 18 is connected with a DC power supply 20. If a positive DC voltage is supplied to the electrostatic electrode plate 18, a negative potential is generated on the wafer W's surface (hereinafter, referred to as “rear surface”) facing the electrostatic chuck 19, and, thus, a potential difference is made between the electrostatic electrode plate 18 and the rear surface of the wafer W. Accordingly, the wafer W is attracted to and held on the electrostatic chuck 19 by Coulomb force or Johnson-Rahbek force caused by the potential difference.

Further, a ring-shaped focus ring 21 is mounted on the susceptor 12 so as to surround the wafer W attracted to and held on the electrostatic chuck 19. The focus ring 21 is made of a conductive material such as single crystalline silicon which is the same material as that of the wafer W. Since the focus ring 21 is made of the conductive material, plasma can be distributed not only on the wafer W but also on the focus ring 21. Therefore, a plasma density on a peripheral portion of the wafer W can be maintained at the substantially same level as a plasma density on a central portion of the wafer W. Accordingly, it is possible to maintain uniformity of the dry etching process to be performed on the entire surface of the wafer W.

A shower head 22 serving as a facing electrode is installed above the susceptor 12 so as to face the susceptor 12. The shower head 22 includes a conductive upper electrode layer 24 having a plurality of gas holes 23 and a supporting member 25 which is attachably/detachably holding the upper electrode layer 24. Installed at the upper part of the shower head 22 is a temperature control device 30 for controlling a temperature of the shower head 22.

The temperature control device 30 includes a heating layer 31 positioned at the lower side to face the upper electrode layer 24 as a heating target member, a heat insulating layer 32 positioned in contact with an opposite surface to the heating layer 31's surface facing the upper electrode layer 24, and a cooling layer 33 positioned in contact with an opposite surface to the heat insulating layer 32's surface facing the heating layer 31. The heating layer 31, the heat insulating layer 32, and the cooling layer 33 are covered by a protection layer 34. The heating layer 31, the heat insulating layer 32, and the cooling layer 33 are arranged to be overlapped with the upper electrode layer 24 as a heating target member when viewed from the top. Therefore, temperature uniformity within the upper electrode layer 24 can be achieved.

The heating layer 31 may be, e.g., a sheath heater. As a coolant for the cooling layer 33, low-cost tap water may be used. A temperature of the water may be about 30° C. or lower, for example, in the range from about 15° C. to about 30° C. The tap water serving as a coolant is consecutively supplied and discharged during an operation of the temperature control device 30, and, thus, any active control of its flow rate and temperature is not performed. The supply amount of the water is in the range from about 1 liter/min to about 4 liter/min, for example. If the water temperature is in the above-mentioned range, it may be recycled.

The cooling layer 33 cools the upper electrode layer 24 serving as a heating target member via the heat insulating layer 32 and the heating layer 31. A heating state of the heating layer 31 is adjusted according to a heating target temperature of the upper electrode layer 24.

The temperature control device 30 includes the heating layer 31, the heat insulating layer 32, and the cooling layer 33, for which running water is used as a coolant, in sequence to face the upper electrode layer 24. After selecting of a heating temperature of the heating layer 31 and a material and thickness of the heat insulating layer 32, a surface (a lowermost surface in FIG. 1) of the upper electrode layer 24 can be heated to a target temperature of, e.g., 220° C. by means of a heat balance between direct heating of the heating layer 31 to the shower head 22 and indirect cooling of the cooling layer 33 via the heat insulating layer 32. At this time, the water serving as a coolant for the cooling layer 33 does not boils. There will be described later a selection of the heating temperature of the heating layer 31 and the material and thickness of the heat insulating layer 32, and a heat balance between heating and cooling.

A shaft 26 penetrates the cover 13 and an upper portion of the shaft 26 is connected with a lift mechanism (not illustrated) positioned above the substrate processing apparatus 10. The lift mechanism is configured to move the shaft 26 in a vertical direction of the drawing, and at the same time, the shower head 22 including the upper electrode layer 24 vertically moves like a piston within the chamber 11. Accordingly, a gap, i.e., a thickness of a space, between the shower head 22 and the susceptor 12 can be adjusted. The maximum moving distance of the shower head 22 in the vertical direction of the drawing is about 70 mm, for example.

There is a possibility of a friction between the shaft 26 and the cover 13, which may be a cause to make particles. Therefore, a side surface of the shaft 26 is covered by, e.g., a bellows 27. An upper end of the bellows 27 is joined to the bottom surface of the cover 13 and a lower end thereof is joined to the top surface of the temperature control device 30. With this configuration, the inside of the chamber 11 remains separated/isolated from the atmosphere.

The operations of respective components such as the first high frequency power supply 14 or the second high frequency power supply 16 of the substrate processing apparatus 10, and the heating temperature of the temperature control device 30 are controlled by a CPU of a controller (not illustrated) provided in the substrate processing apparatus 10 according to a program corresponding to a dry etching process.

In the substrate processing apparatus 10 configured as described above, a temperature of the upper electrode layer 24 is controlled to a temperature of, e.g., about 220° C. by the temperature control device 30, and a processing gas is supplied between the susceptor 12 and the shower head 22 in the chamber 11 through a non-illustrated processing gas supply line. The supplied processing gas is excited into plasma by a plasma-generating power applied into the chamber 11.

Positive ions in the plasma are attracted toward the wafer W mounted on the susceptor 12 by a negative bias potential caused by a bias power supplied to the susceptor 12, and then a dry etching process is performed.

Hereinafter, there will be explained properties of each layer and a heat balance between heating and cooling in the temperature control device 30.

Heat transfer areas S of the upper electrode layer (hereinafter, referred to as “UEL”) 24 serving as a heating target member, the heating layer 31, and the heat insulating layer 32 were set to about 0.163 m², thermal conductivities λ thereof were set to about 229.04 W/m·K, about 229.04 W/m·K, and about 0.22 W/m·K, respectively (heat insulating material: polytetrafluoroethylene (PTFE)), and thicknesses of the UEL 24 and the heating layer 31 were set to about 0.020 m and 0.015 m, respectively. Then, by sequentially varying a thickness of the heat insulating layer 32, it was possible to obtain the thickness of the heat insulating layer 32 suitable for heating the UEL 24 to the target temperature of about 220° C. The obtained thickness in the experiment was in the range from about 0.001 m to about 0.005 m.

Table 1 shows properties of each layer in the temperature control device 30. Table 2 shows an absorbed heat amount and a difference in a coolant temperature between inflow and outflow to/from the heat insulating layer 32 when the thickness of the heat insulating layer 32 was set to be in the range from about 0.001 m to about 0.005 m.

TABLE 1

| | | | Heat | |
|---|---|---|---|---|
| | | Heating | insulating | Cooling |
| | UEL | layer | layer | layer |
| Heat transfer area | 0.163 | 0.163 | 0.163 | |
| S(m²) | | | | |
| Thermal conductivity | 229.04 | 229.04 | 0.22 | 0.63 |
| λ(W/m · K) | | | | |
| Thickness(m) | 0.020 | 0.015 | — | — |
| Supply amount of | — | — | — | 3.3 × 10⁻⁵ |
| water(m³/s) | | | | |
| Supply temperature | — | — | — | 5.508 |
| of water (° C.) | | | | |

TABLE 2

| | Temperature | |
|---|---|---|
| | difference between | |
| | inflow and outflow | Absorbed heat |
| | (° C.) | amount(ΔQ) |
| Heat insulating layer's | 11.5 | 1.603 |
| thickness d = 0.001(m) | | |
| Heat insulating layer's | 6.4 | 0.892 |
| thickness d = 0.003(m) | | |
| Heat insulating layer's | 3.1 | 0.432 |
| thickness d = 0.005(m) | | |

An absorbed heat amount (ΔQ) in the cooling layer 33 is represented as follows.

ΔQ=Qi+Qh+Qu (3-1)

Here, Qi denotes an absorbed heat amount in the heat insulating layer, Qh denotes an absorbed heat amount in the heating layer, and Qu denotes an absorbed heat amount in the UEL.

Table 3 shows actual measurement values obtained when a temperature of the heating layer 31's surface facing the heat insulating layer 32 is denoted by t1° C., a temperature of the heating layer 31's surface facing the UEL 24 is denoted by t2° C., and the thickness of the heat insulating layer 32 is set to be about 0.001 m and about 0.005 m in which a temperature can be controlled (here, a temperature of the top surface of the heat insulating layer 32: ti° C. and a temperature of the lower portion of the UEL 24: tu° C.). These measurement values are substituted into the following equations.

Qi=λi·S·(t1−ti)/d (3-2)

Qh=λh·S·(t2−t1)/15×10⁻³ (3-3)

Qu=λu·S·(t2−tu)/20×10⁻³ (3-4)

Based on the equations (3-1) to (3-4), the following inequality can be obtained.

0.56·t1+77≦t2≦0.57·t1+82 (3)

TABLE 3

| | Heat insulating layer 32's | | | |
|---|---|---|---|---|
| | thickness: d(m) | | | |
| | 0 | 0.001 | 0.003 | 0.005 |
| Temperature of heat insulating | (=t1) | 126.5 | 128.7 | 129.5 |
| layer 32's top surface: ti(° C.) | | | | |
| Temperature of UEL 24's lower | 175.3 | 176.5 | 183.7 | 190.5 |
| portion: tu(° C.) | | | | |

Therefore, it can be seen that if the temperature t2 of the heating layer 31's surface facing the UEL 24 is equal to or higher than 0.56·t1+77 and equal to or lower than 0.57·t1+82, a temperature can be controlled in a favorable manner.

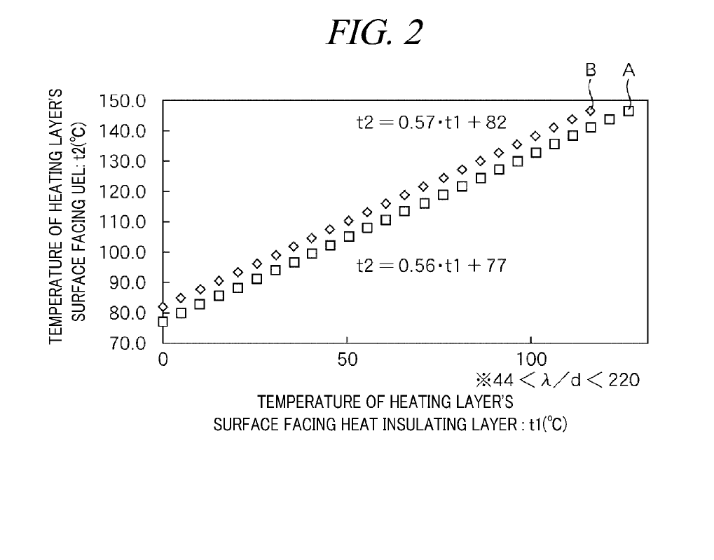

FIG. 2 is a graph showing a relationship between a temperature t1 of the heating layer 31's surface facing the heat insulting layer 32 and a temperature t2 of the heating layer 31's surface facing the UEL 24.

In FIG. 2, A represents a case of t2=0.56·t1+77 and B represents a case of t2=0.57·t1+82. If t2 has a value in the range between A and B, a temperature can be controlled well in such a range.

Further, if the above-described conditions are satisfied, λ/d can be represented as below.

λ/d=(−26721·t2+15269+t1+2109195)/(t1−128.7) (2)

Furthermore, if a thermal conductivity A of the heat insulting layer 32 with which a temperature can be controlled in a favorable manner and each of its minimum thickness d of about 0.001 m and its maximum thickness d of 0.005 m are substituted into λ/d, the following inequality can be obtained:

44<λ/d<220 (1)

From the above results, in the present embodiment, it is desirable for λ/d in the heat insulating layer 32 to satisfy the following inequality.

44<λ/d<220 (1)

It is more desirable to satisfy the following equation.

λ/d=(−26721·t2+15269·t1+2109195)/(t1−128.7) (2)

The heat insulating layer 32 can be made of any other materials satisfying equation (1) other than PTFE, such as polyetheretherketone (PEEK), vespel, Bakelite or other resin.

In the present embodiment, if the temperature of the heating layer 31's surface facing the heat insulating layer is denoted by t1° C. and the temperature of the heating layer 31's surface facing the UEL 24 is denoted by t2° C., it is desirable for t2 to satisfy the following inequality.

0.56·t1+77≦t2≦0.57·t1+82 (3)

If t2 has a value in the range satisfying inequality (3), a temperature can be controlled with favorable responsiveness to heating and cooling.

In accordance with the present embodiment, the temperature control device 30 includes the heating layer 31 positioned to face the UEL 24, the heat insulating layer 32 positioned in contact with an opposite surface to the heating layer 31's surface facing the UEL 24, and the cooling layer 33 positioned in contact with an opposite surface to the heat insulating layer 32's surface facing the heating layer 31. Therefore, at the time of heating the UEL 24, the UEL 24 is heated by the heating layer 31, and cooled by the cooling layer 33. At this time, the heat insulating layer 32 prevents supercooling by the cooling layer 33. At the time of cooling the UEL 24, the UEL 24 is cooled by the cooling layer 33 but not heated by the heating layer 31 any longer. At this time, a heat insulating effect of the heat insulating layer 32 does not cause a serious problem in cooling the UEL 24, and the UEL 24 is cooled gradually in a favorable manner.

In the present embodiment, there has been explained a case where the temperature control device 30 is employed to the substrate processing apparatus 10 including a movable electrode, but the substrate processing apparatus 10 is not limited to the movable electrode type. Therefore, the temperature control device 30 can be employed to any apparatus including a stationary electrode serving as a heating target member such as an electrode plate to which a radiant heat from plasma is inputted.

In the present embodiment, a heating source of the heater in the heating layer 31 may be divided into a center source and an edge source, and either one or both of the two sources may be used.

In the present embodiment, the heating layer 31 of the temperature control device 30 may be controlled by a feedback control such as a PID control.

### Experimental Example

Hereinafter, an experimental example of the present invention will be explained in detail.

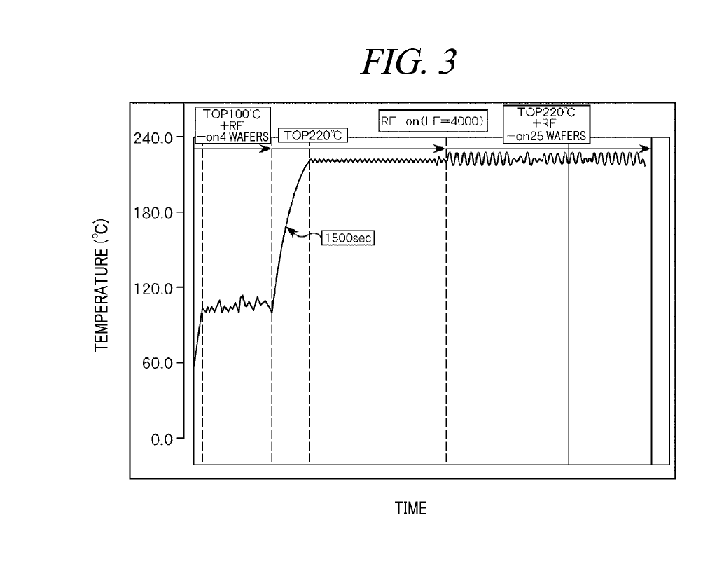

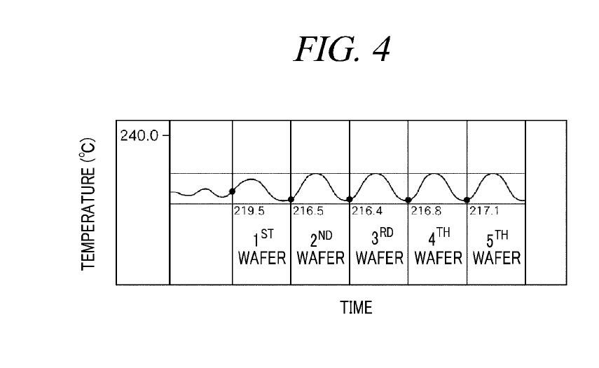

A polytetrafluoroethylene (PTFE) was used as a heat insulating material of the heat insulating layer 32; the thickness of the heat insulating layer 32 was about 0.003 m; the temperature control device 30 having the same conditions as described in Tables 1 and 2 was used to heat the shower head 22 serving as an upper electrode member to the temperature of about 100° C. Then, a first plasma process was performed on a wafer W at the temperature of about 100° C. Then, the UEL 24 was heated to the temperature of about 220° C. and after a predetermined time period, a second plasma process was performed on another wafer W. The results thereof are shown in FIGS. 3 and 4.

FIG. 3 is a graph showing changes in a temperature of the UEL 24 in accordance with the present experimental example, and FIG. 4 is an enlarged view of a part of FIG. 3.

As depicted in FIG. 3, a temperature of the UEL 24 serving as a heating target member was gradually increased from a start of heating and reached about 100° C. after about 8.3 minutes from the start of heating. At the temperature of about 100° C., four sheets of wafers W were plasma-processed by applying high frequency powers such as a plasma-generating power (about 100 MHz, about 1000 W) and a bias power (about 3.2 MHz, about 4000 W). Then, after a stop of application of the high frequency powers, the UEL 24 was further heated for about 25 minutes and reached the temperature of about 220° C. With the temperature of about 220° C. maintained for about 87 minutes, twenty five sheets of target wafers were plasma-processed by applying the high frequency powers such as the plasma-generating power (about 100 MHz, about 1000 W) and the bias power (about 3.2 MHz, about 4000 W). As a result, even though there is an inputted heat from plasma radiation, the temperature of the UEL 24 can be controlled in a favorable manner. Further, the temperature of about 220° C. corresponds to a temperature at which a deposit is suppressed from being deposited in the plasma process.

As can be seen from FIG. 4, when the wafers W were plasma-processed at about 220° C., the temperature was changed at a micro level but constantly maintained at about 220° C.±15° C. Further, if the thickness of the heat insulating layer 32 is too thick, the temperature cannot be controlled well and the graph shows a rising tendency. If the thickness is too thin, the temperature cannot be controlled well and the graph shows a falling tendency.

In the present experimental example, it is also possible to generate plasma by using an increased high frequency powers such as a plasma-generating power (about 100 MHz, about 1000 W) and a bias power (about 3.2 MHz, about 4500 W).

In the above-described embodiment and experimental example, there has been used a wafer for a semiconductor device as a substrate to be dry-etched. However, the substrate to be dry-etched is not limited thereto and may be a glass substrate such as a flat panel display (FPD) including a liquid crystal display (LCD).

What is claimed is:

1. A temperature control device for controlling a temperature of a member to be exposed to plasma in a substrate processing apparatus that includes a mounting electrode for mounting a target substrate and a facing electrode positioned to face the mounting electrode, excites a processing gas supplied between the mounting electrode and the facing electrode into plasma, and performs a plasma process on the target substrate with the plasma, the temperature control device comprising:
a heating layer configured to heat a heating target member;
a heat insulating layer positioned in contact with an opposite surface to a heating layer's surface facing the heating target member; and
a cooling layer positioned in contact with an opposite surface to a heat insulating layer's surface facing the heating layer.

2. The temperature control device of claim 1, wherein a coolant for the cooling layer is running water and a temperature of water discharged from the cooling layer does not exceed a boiling point of water.

3. The temperature control device of claim 1, wherein if a thermal conductivity of the heat insulating layer is denoted by λ(W/m·K) and its thickness is denoted by d(m), λ/d satisfies an inequality (1).
44<λ/d<220 (1)

4. The temperature control device of claim 2, wherein if a thermal conductivity of the heat insulating layer is denoted by λ(W/m·K) and its thickness is denoted by d(m), λ/d satisfies an inequality (1).
44<λ/d<220 (1)

5. The temperature control device of claim 3, wherein if a temperature of the heating layer's surface facing the heat insulating layer is denoted by t1° C. and a temperature of the heating layer's surface facing the heating target member is denoted by t2° C., λ/d satisfies an equality (2).
λ/d=(−26721·t2+15269·t1+2109195)/(t1−128.7) (2)

6. The temperature control device of claim 4, wherein if a temperature of the heating layer's surface facing the heat insulating layer is denoted by t1° C. and a temperature of the heating layer's surface facing the heating target member is denoted by t2° C., λ/d satisfies an equality (2).
λ/d=(−26721·t2+15269·t1+2109195)/(t1−128.7) (2)

7. The temperature control device of claim 1, wherein if a temperature of the heating layer's surface facing the heat insulating layer is denoted by t1° C. and a temperature of the heating layer's surface facing the heating target member is denoted by t2° C., t2 satisfies an inequality (3).
0.56·t1+77≦t2≦0.57·t1+82 (3)

8. The temperature control device of claim 2, wherein if a temperature of the heating layer's surface facing the heat insulating layer is denoted by t1° C. and a temperature of the heating layer's surface facing the heating target member is denoted by t2° C., t2 satisfies an inequality (3).
0.56·t1+77≦t2≦0.57·t1+82 (3)

9. The temperature control device of claim 3, wherein if a temperature of the heating layer's surface facing the heat insulating layer is denoted by t1° C. and a temperature of the heating layer's surface facing the heating target member is denoted by t2° C., t2 satisfies an inequality (3).
0.56·t1+77≦t2≦0.57·t1+82 (3)

10. The temperature control device of claim 4, wherein if a temperature of the heating layer's surface facing the heat insulating layer is denoted by t1° C. and a temperature of the heating layer's surface facing the heating target member is denoted by t2° C., t2 satisfies an inequality (3).
0.56·t1+77≦t2≦0.57·t1+82 (3)

11. The temperature control device of claim 5, wherein if a temperature of the heating layer's surface facing the heat insulating layer is denoted by t1° C. and a temperature of the heating layer's surface facing the heating target member is denoted by t2° C., t2 satisfies an inequality (3).
0.56·t1+77≦t2≦0.57·t1+82 (3)

12. The temperature control device of claim 6, wherein if a temperature of the heating layer's surface facing the heat insulating layer is denoted by t1° C. and a temperature of the heating layer's surface facing the heating target member is denoted by t2° C., t2 satisfies an inequality (3).
0.56·t1+77≦t2≦0.57·t1+82 (3)

13. The temperature control device of claim 1, wherein the heating target member is an electrode plate of the facing electrode and is installed above the mounting electrode to face the mounting electrode.

14. A temperature control method for controlling a temperature of a member to be exposed to plasma in a substrate processing apparatus that includes a mounting electrode for mounting a target substrate and a facing electrode positioned to face the mounting electrode, excites a processing gas supplied between the mounting electrode and the facing electrode into plasma, and performs a plasma process on the target substrate with the plasma, the temperature control method comprising:
using a temperature control device which includes a heating layer configured to heat a heating target member, a heat insulating layer positioned in contact with an opposite surface to a heating layer's surface facing the heating target member, and a cooling layer positioned in contact with an opposite surface to a heat insulating layer's surface facing the heating layer; and
adjusting a temperature of the heating target member to a predetermined temperature by maintaining a balance between heating and cooling by increasing or decreasing a heating temperature of the heating layer while cooling the heating target member with running water serving as a coolant for the cooling layer.

15. The temperature control method of claim 14, wherein the predetermined temperature is in a range from about 60° C. to about 220° C.

16. A substrate processing apparatus that includes a mounting electrode for mounting a target substrate and a facing electrode positioned to face the mounting electrode, excites a processing gas supplied between the mounting electrode and the facing electrode into plasma, and performs a plasma process on the target substrate with the plasma, the substrate processing apparatus comprising:
a temperature control device as claimed in claim 1 for controlling a temperature of a member to be exposed to the plasma.
